(19) United States
(12) Patent Application Publication
(10) Pub. No.: US 2010/0078129 A1
(43) Pub. Date: Apr. 1, 2010

(54) MOUNTING TABLE FOR PLASMA PROCESSING APPARATUS

(75) Inventors: Shinji HIMORI, Nirasaki City (JP); Yasuharu SASAKI, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/560,865

(22) Filed: Sep. 16, 2009

(30) Foreign Application Priority Data
Sep. 26, 2008 (JP) 2008-248178

(51) Int. Cl. H01L 21/465

(52) U.S. Cl. 156/345.43; 156/345.51; 257/E21.485

(57) ABSTRACT

A mounting table for use in a plasma processing apparatus, on which a substrate is mounted, includes: an inner conductive member connected to an ion attracting RF power supply; an outer conductive member connected to a plasma generating RF power supply, the outer conductive member surrounding the inner conductive member; and a partition member formed of a dielectric material, the partition member partitioning between the inner conductive member and the outer conductive member. Further, the mounting table includes an electrostatic chuck formed of a dielectric material and arranged between the substrate and the inner conductive member, and between the substrate and the outer conductive member; and a dielectric layer arranged between the electrostatic chuck and the inner conductive member to conceal the inner conductive member from the electrostatic chuck. The electrostatic chuck includes an electrode film that is connected to a high voltage DC power supply.

### CROSS-REFERENCE TO RELATED APPLICATIONS

This application claims priority to Japanese Patent Application No., 2008-248178 filed on Sep. 26, 2008, the entire contents of which are hereby incorporated by reference.

### FIELD OF THE INVENTION

The present invention relates to a mounting table for plasma processing apparatus, of mounting thereon a substrate which is subjected to a plasma processing, and more particularly, to a mounting table in which a dielectric layer is embedded.

### BACKGROUND OF THE INVENTION

In a process of manufacturing a semiconductor device, a plasma process, such as dry etching or ashing, is performed on a semiconductor wafer by using a plasma generated from a process gas. In a plasma processing apparatus performing the plasma process, for example, a pair of parallel electrodes, each having a plate shape, are positioned in parallel one above the other. High frequency power is applied between the pair of parallel plates to generate a plasma from a process gas. When the plasma process is carried out, the wafer is mounted on a lower electrode serving as a mounting table.

With an increasing demand for a plasma which has low ion energy and high electron density, high frequency power applied between the electrodes tends to have a very high frequency, e.g., 100 MHz, compared to conventional frequencies of, e.g., less than 20 MHz. However, it has been observed that if the frequency of the applied high frequency power rises, an electric field is strengthened at a space above the center of the surface of the electrode, i.e. the center of the wafer, but is weakened at a space above a peripheral portion of the surface of the electrode. Such non-uniform distribution in electric field may cause a non-uniform electron density in the plasma, so that, e.g., etching rate may vary depending on a position within the wafer in dry etching using ions. Thus, a problem may occur in that satisfactory in-plane uniformity can not be obtained in dry etching.

In order to cope with this problem, there is disclosed a plasma processing apparatus, which can make the electric field strength distributed uniformly and improve in-plane uniformity in a plasma process by embedding a dielectric layer formed of, e.g., a ceramic, at the central of a top surface region of the lower electrode, i.e., mounting table (see, e.g., Japanese Patent Laid-open Application No. 2004-363552 and corresponding U.S. Patent Application Publication No. 2005/0276928 A1).

As shown in FIG. 10A, when high frequency power is applied from a high frequency power supply 82 to a lower electrode 81 in a plasma processing apparatus 80, a high frequency current flows along a surface of the lower electrode 81 to an upper part thereof by the skin effect, and then flows through a wafer W toward the central portion thereof. At this time, a part of the current leaks from the central portion of the wafer to the lower electrode 81 and then flows outward inside the lower electrode 81.

Here, the high frequency current may more deeply penetrate into the portion of the lower electrode 81 at which a dielectric layer 83 is embedded than the other portions of the lower electrode 81; and accordingly, a hollow cylindrical resonance of TM mode is generated at the central portion of the lower electrode 81. Consequently, the electric field strength can be lowered at a space above the central portion of the wafer W, to thereby make the electric field strength uniformly distributed at the space above the wafer W.

Since a plasma process is normally conducted under a depressurized atmosphere, an electrostatic chuck 84 is used to firmly mount the wafer W in the plasma processing apparatus 80 as shown in FIG. 10B. A conductive electrode film 85 is interposed between a lower member and an upper member, which are formed of a dielectric material, e.g., alumina, in the electrostatic chuck 84. During a plasma processing, high voltage DC power is supplied from a high voltage DC power supply 86 to the electrode film 85 to generate a coulomb force on a surface of the upper member of the electrostatic chuck 84, whereby the wafer W is electrostatically adsorbed and fixed.

Each component of the plasma processing apparatus 80 can be treated as a component of an electric circuit for a high frequency current. Further, the wafer W is formed of a semiconductor such as silicon, and thus, the wafer W is also considered as a component of the electric circuit. Since the wafer W is mounted in parallel with the electrode film 85 when the wafer W is electrostatically attracted to the electrostatic chuck 84, the wafer W and the electrode film 85 are considered to serve as resistors arranged in parallel in the electric circuit.

As a consequence, the value of a high frequency current flowing through the wafer W is dependent on a resistance of the wafer W and a resistance of the electrode film 85. For instance, when the resistance of the electrode film 85 is larger than that of the wafer W, high frequency current mainly flows from a peripheral portion to the central portion of the wafer W (see FIG. 11A). In such a case, a large potential difference occurs between the peripheral portion of the wafer W and the central portion of the wafer W as shown in FIG. 11B, so that a gate oxide film 87 is charged up and deteriorated.

Further, when the resistance of the electrode film 85 is very small, the high frequency current leaking from the central portion of the wafer W to the lower electrode 81 side can readily flow through the electrode film 85, and thus the high frequency current can not penetrate deep into the central portion. As a consequence, a hollow cylindrical resonance of TM mode is not produced and the electric field strength is non-uniformly distributed, which causes electron density of a plasma to be increased in a space above the central portion of the wafer W. Accordingly, a DC-like current flows between the central portion and the peripheral portion of the wafer W. This case also has the same problem as that described above in that the gate oxide film 87 of semiconductor devices disposed on the wafer W is charged up and deteriorated.

### SUMMARY OF THE INVENTION

In view of the above, the present invention provides a mounting table capable of preventing deterioration of an insulation film of semiconductor devices disposed on a substrate.

In accordance with a first aspect of the present invention, there is provided a mounting table for use in a plasma processing apparatus, on which a substrate is mounted, including: an inner conductive member connected to an ion attracting RF power supply; an outer conductive member connected to a plasma generating RF power supply, the outer conductive member surrounding the inner conductive member; a partition member formed of a dielectric material, the partition member partitioning between the inner conductive member and the outer conductive member; an electrostatic chuck formed of a dielectric material and arranged between the substrate and the inner conductive member, and between the substrate and the outer conductive member; and a dielectric layer arranged between the electrostatic chuck and the inner conductive member to conceal the inner conductive member from the electrostatic chuck, wherein the electrostatic chuck includes an electrode film that is connected to a high voltage DC power supply and satisfies the following condition:

δ/z≧85,

where δ=(ρᵥ/(μnf))^{1/2}, and z refers to a thickness of the electrode film; δ, to a skin depth of the electrode film relative to high frequency power supplied from the high frequency power supply for generating a plasma; f, to a frequency of high frequency power supplied from the high frequency power supply for generating a plasma; n, to a circular constant; μ, to a magnetic permeability of the electrode film; and ρᵥ, to a resistivity of the electrode film.

In accordance with a second aspect of the present invention, there is provided a mounting table for use in a plasma processing apparatus, on which a substrate is mounted, including: an inner conductive member connected to an ion attracting RF power supply; an outer conductive member connected to a plasma generating RF power supply, the outer conductive member surrounding the inner conductive member; a partition member formed of a dielectric material, the partition member partitioning between the inner conductive member and the outer conductive member from each other; an electrostatic chuck formed of a dielectric material and arranged between the substrate and the inner conductive member, and between the substrate and the outer conductive member; and a dielectric layer arranged between the electrostatic chuck and the inner conductive member to conceal the inner conductive member from the electrostatic chuck, wherein the electrostatic chuck includes an electrode film that is connected to a high voltage DC power supply and satisfies the following condition:

115 Ω/□≦ρₛ,

where ρₛ refers to a surface resistivity of the electrode film.

In accordance with a third aspect of the present invention, there is provided a mounting table for use in a plasma processing apparatus, on which a substrate is mounted, including: an inner conductive member connected to an ion attracting RF power supply and a plasma generating RF power supply; an outer conductive member surrounding the inner conductive member; a partition member formed of a dielectric material, the partition member partitioning between the inner conductive member and the outer conductive member; an electrostatic chuck formed of a dielectric material and arranged between the substrate and the inner conductive member, and between the substrate and the outer conductive member; and a dielectric layer arranged between the electrostatic chuck and the inner conductive member to conceal the inner conductive member from the electrostatic chuck, wherein the electrostatic chuck includes an electrode film that is connected to a high voltage DC power supply, wherein a dielectric constant of the partition member ranges from 10 to 130, and wherein the electrode film satisfies the following condition:

δ/z≧85,

where δ=(ρᵥ/(μnf))^{1/2}, and z refers to a thickness of the electrode film; δ, to a skin depth of the electrode film relative to high frequency power supplied from the plasma generating RF power supply; f, to a frequency of high frequency power supplied from the plasma generating RF power supply; n, to the circular constant; μ, to a magnetic permeability of the electrode film; and ρᵥ, to a resistivity of the electrode film.

In accordance with a fourth aspect of the present invention, there is provided a mounting table for use in a plasma processing apparatus, on which a substrate is mounted, including: an inner conductive member connected to an ion attracting RF power supply and a plasma generating RF power supply; an outer conductive member surrounding the inner conductive member; a partition member formed of a dielectric material, the partition member partitioning between the inner conductive member and the outer conductive member; an electrostatic chuck formed of a dielectric material and arranged between the substrate and the inner conductive member, and between the substrate and the outer conductive member; and a dielectric layer arranged between the electrostatic chuck and the inner conductive member to conceal the inner conductive member from the electrostatic chuck, wherein the electrostatic chuck includes an electrode film that is connected to a high voltage DC power supply, wherein a dielectric constant of the partition member ranges from 10 to 130, and wherein the electrode film satisfies the following condition:

115 Ω/ε≦ρₛ,

where ρₛ refers to a surface resistivity of the electrode film.

### BRIEF DESCRIPTION OF THE DRAWINGS

The objects and features of the present invention will become apparent from the following description of embodiments, given in conjunction with the accompanying drawings, in which:

FIG. 1 is a cross sectional view schematically illustrating a configuration of a plasma processing apparatus having a mounting table in accordance with an embodiment of the present invention;

FIG. 2 is an expanded cross sectional view schematically illustrating a configuration around a mounting table in accordance with the embodiment of the present invention;

FIG. 3 is a graph illustrating an etching rate distribution of a photoresist in a surface of each wafer when a plurality of electrode films, each having a different δ/z value from that of the others, are used;

FIGS. 4A and 4B depict simulation results of a potential distribution in a wafer when a resistivity of the wafer is changed while a frequency of high frequency power supplied from an ion attracting RF power supply is 2 MHz, wherein FIG. 4A is a graph of illustrating simulation results for a conventional mounting table, and FIG. 4B is a graph of illustrating simulation results for a mounting table in accordance with the embodiment of the present invention;

FIGS. 5A and 5B depict simulation results of a potential distribution in a wafer when a resistivity of the wafer is changed while a frequency of high frequency power supplied from an ion attracting RF power supply is 13 MHz, wherein FIG. 5A is a graph of illustrating simulation results for a conventional mounting table, and FIG. 5B is a graph of illustrating simulation results for a mounting table in accordance with the embodiment of the present invention;

FIGS. 6A and 6B depict simulation results of a sheath electric field strength distribution in a processing space when a frequency of high frequency power supplied from a high frequency power supply for generating a plasma is 100 MHz, wherein FIG. 6A is a graph illustrating simulation results of a conventional mounting table and FIG. 6B is a graph illustrating simulation results of a mounting table in accordance with the embodiment of the present invention;

FIGS. 7A and 7B depict simulation results of a sheath electric field strength distribution in a processing space when a frequency of high frequency power supplied from a high frequency power supply for generating a plasma is 40 MHz, wherein FIG. 7A is a graph illustrating simulation results in a conventional mounting table and FIG. 7B is a graph illustrating simulation results in a mounting table in accordance with the embodiment of the present invention;

FIG. 8 is an expanded cross sectional view schematically illustrating a configuration around a mounting table in accordance with a second embodiment of the present invention;

FIG. 9 is a graph illustrating simulation results of a sheath electric field strength distribution in a processing space when a dielectric constant of a partition member is changed;

FIGS. 10A and 10B schematically illustrate configurations of conventional plasma processing apparatus that may enhance in-plane uniformity of plasma processing, wherein FIG. 10A is a cross sectional view illustrating a plasma processing apparatus without an electrostatic chuck, and FIG. 10B is a cross sectional view illustrating a plasma processing apparatus with an electrostatic chuck; and

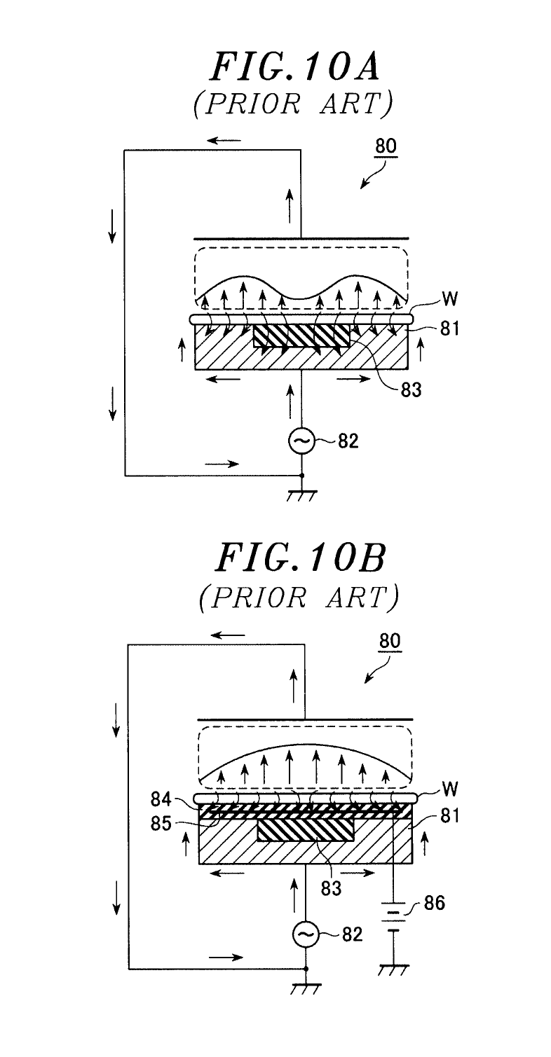

FIGS. 11A and 11B illustrate a high frequency current at an electrode film of a mounting table included in a conventional plasma processing apparatus and a potential at a wafer thereof, wherein FIG. 11A is a view illustrating flow of a high frequency current and FIG. 11B is a view illustrating a potential distribution in the wafer.

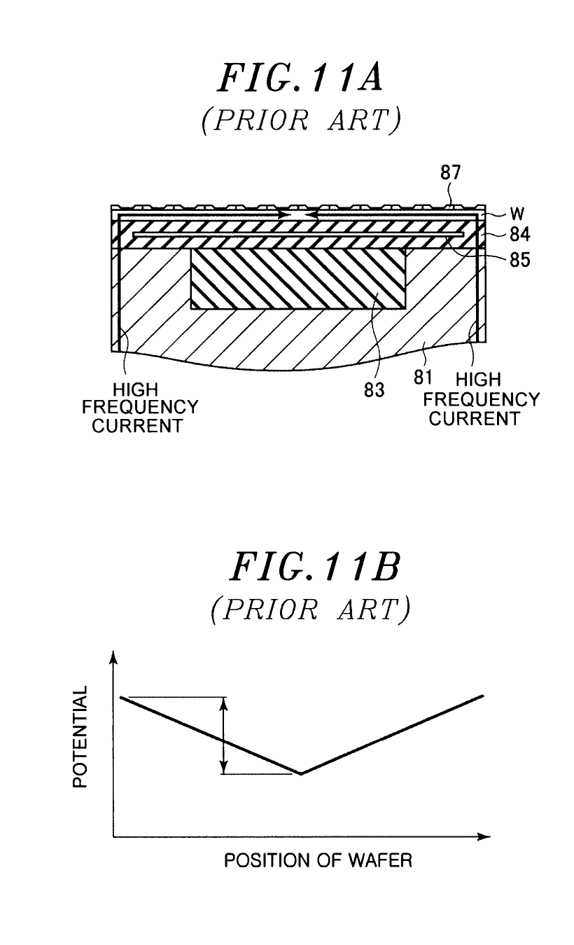

### DETAILED DESCRIPTION OF THE EMBODIMENTS

Hereinafter, embodiments of the present invention will be described in detail with reference to accompanying drawings which form a part hereof.

First of all, a mounting table in accordance with a first embodiment of the present invention will be described.

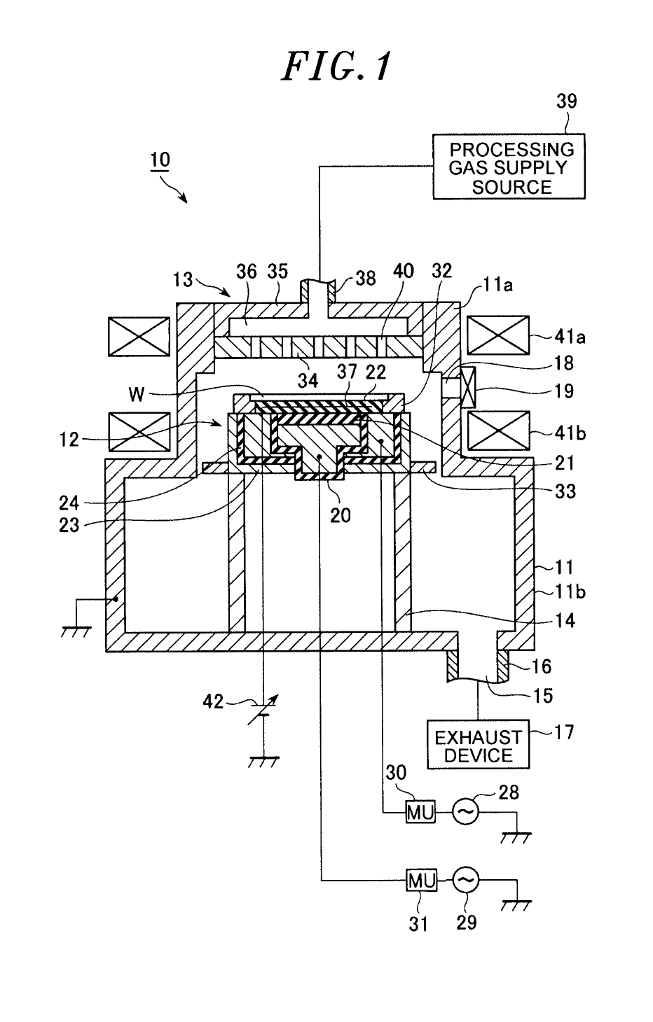

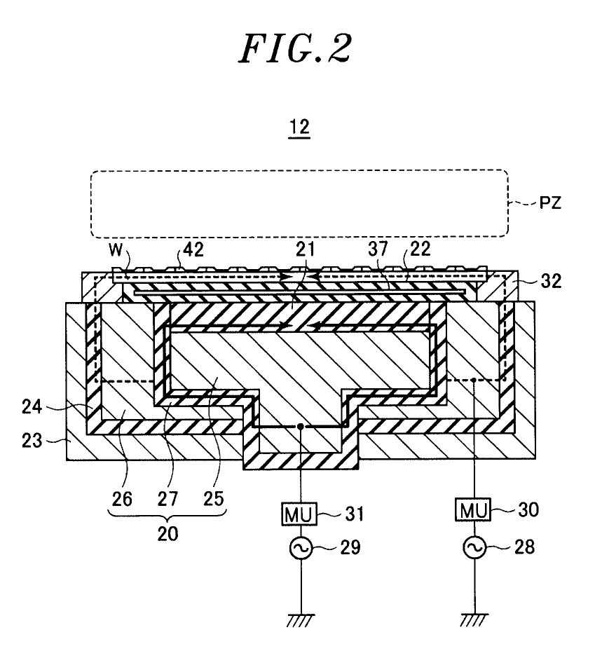

FIG. 1 is a cross sectional view schematically illustrating a configuration of a plasma processing apparatus having a mounting table in accordance with an embodiment of the present invention, and FIG. 2 is an expanded cross sectional view schematically illustrating a configuration around a mounting table in accordance with an embodiment of the present invention. The plasma processing apparatus is configured to perform plasma etching, for example, RIE (Reactive Ion Etching) or ashing on a semiconductor wafer (substrate) having a diameter of, e.g., 300 mm.

Referring to FIG. 1, the plasma processing apparatus 10 includes a processing vessel 11 formed of, e.g., a vacuum chamber, a mounting table 12 supported by a supporting case 14 disposed on a central part of the bottom wall of the processing vessel 11, and an upper electrode 13 disposed above and in parallel with the mounting table 12.

The processing vessel 11 has a cylindrical upper chamber 11a having a smaller diameter and a cylindrical lower chamber 11b having a larger diameter chamber. The upper chamber 11a and the lower chamber 11b communicate with each other, and the overall processing vessel 11 is configured to be airtightly sealed. The mounting table 12 and the upper electrode 13 are accommodated in the upper chamber 11a, and the supporting case 14 that supports the mounting table 12 and has pipes for a coolant and a backside gas therein is disposed in the lower chamber 11b.

An exhaust port 15 is prepared at the bottom of the lower chamber 11b and an exhaust system 17 is connected to the exhaust port 15 via an exhaust pipe 16. The exhaust system 17 includes, e.g., an APC (Adaptive Pressure Control) valve, a DP (Dry Pump) and TMP (Turbo Molecular Pump) (all not shown), which are controlled by a signal from a controller (not shown) so that the whole inner space of the processing vessel 11 is vacuum exhausted to maintain a desired vacuum level. Further, a transfer port 18 for transferring a wafer W is provided at a side wall of the upper chamber 11a to be opened and closed by a gate valve 19. The upper chamber 11a and the lower chamber 11b are formed of a conductive member such as aluminum and grounded.

The mounting table 12 includes a table-shaped lower electrode 20; a dielectric layer 21 formed of a dielectric material such as a ceramic and substantially shaped as a circular plate to make an electric field strength uniformly distributed in a processing space as described later; and an electrostatic chuck 22 for electrostatically adsorbing the wafer W on a mounting surface.

The electrostatic chuck 22 is formed of a dielectric material and contains a conductive electrode film 37 therein. The electrode film 37 is formed of, for example, an electrode material produced by mixing molybdenum carbide (MoC) with Alumina (Al₂O₃). The electrostatic chuck 22 has a circular plate shape similar to the wafer W to electrostatically adsorb the wafer W securely, and accordingly, the electrode film 37 contained in the electrostatic chuck 22 also has the shape of a circular plate. A high voltage DC power supply 42 is connected to the electrode film 37, and high voltage DC power supplied to the electrode film 37 generates a coulomb force between the mounting surface of the electrostatic chuck 22 and the wafer W to electrostatically adsorb the wafer W.

As shown in FIG. 2, the lower electrode 20 is disposed below and in parallel with a central portion of the wafer W electrostactically adsorbed on a mounting surface. For example, the lower electrode 20 includes an inner conductive member 25 formed of a conductive material, such as aluminum, and having a substantially circular plate shape; an outer conductive member 26 formed of a conductive material, such as aluminum, and having a substantially ring shape, which surrounds a side surface and a bottom surface of the inner conductive member 25 and is disposed below and in parallel with a peripheral portion of the wafer electrostatically adsorbed on the mounting surface; and a partition member 27 formed of a dielectric material such as quartz, and having a cup shape, which serves as a partition between the inner conductive member 25 and the outer conductive member 26. Here, the partition member 27 surrounds only the side surface and bottom surface of the inner conductive member 25 but does not cover a top surface thereof.

A plasma generating RF power supply 28 supplying a high frequency power having a frequency not less than, e.g., 40 MHz, is connected to the outer conductive member 26 via a matching unit (MU) 30. An ion attracting RF power supply 29 supplying a high frequency power having a frequency, e.g., 13.56 MHz or less lower than that of the plasma generating RF power supply 28 is connected to the inner conductive member 25 via a matching unit (MU) 31. The high frequency power supplied from the plasma generating RF power supply 28 generates a plasma from a processing gas as will be described later, and the high frequency power supplied from the ion attracting RF power supply 29 feeds a bias electric power to the wafer so that ions in the plasma are attracted to the wafer W electrostatically adsorbed on the mounting surface.

The lower electrode 20 has a coolant flow path (not shown) through a coolant flows. When a coolant flows through the coolant flow path, the lower electrode 20 is cooled so that the wafer W mounted on a mounting surface of the electrostatic chuck 22 is cooled to a desired temperature. Further, the electrostatic chuck 22 has a through hole (not shown) for discharging a backside gas to raise a heat transfer rate between the mounting surface and a rear surface of the wafer W. A backside gas such as helium (He), which has been supplied from a gas supplier (not shown), is discharged through the through hole.

In the mounting table 12, the electrostatic chuck 22 is arranged directly above the inner conductive member 25 and directly on the outer conductive member 26 between the wafer W and the inner conductive member 25, and between the wafer W and the outer conductive member 26. Further, the dielectric layer 21 is arranged between the electrostatic chuck 22 and the inner conductive member 25, such that the dielectric layer 21 is disposed directly on the inner conductive member 25 to conceal the inner conductive member 25 from the electrostatic chuck 22. As a result, the inner conductive member 25 is partitioned by the dielectric layer 21, the electrostatic chuck 22, and the partition member 27 without directly contacting the outer conductive member 26 and the wafer W.

Further, although in FIG. 2 an outer diameter of the dielectric layer 21 is equal to that of the inner conductive member 25, an outer diameter of the dielectric layer 21 may be set, e.g., to be larger than that of the inner conductive member 25 and disposed between the electrostatic chuck 22 and the inner conductive member 25 such that the dielectric layer 21 is protruded beyond the inner conductive member 25 toward the outer conductive member 26.

Referring back to FIG. 1, a focus ring 32 is arranged at an outer peripheral portion on the top surface of the lower electrode 20 to surround the electrostatic chuck 22. The focus ring 32 expands a plasma in a processing space to wider than a space directly above the wafer W, to enhance the uniformity of etching rate in the surface of the wafer W. Further, the lower electrode 20 is secured on a supporting table 23 disposed on the supporting case 14 via an insulation member 24 and is fully electrically isolated from the processing vessel 11.

A baffle plate 33 is disposed outside of a lower part of the supporting table 23 to surround same. By the baffle plate 33, a processing gas flows from the upper chamber 11a to the lower chamber 11b through a gap provided between the baffle plate 33 and a wall portion of the upper chamber 11a. Namely, the baffle plate 33 serves as a rectifying plate for rectifying flow of the process gas and prevents a plasma from leaking to the lower chamber 11b from the processing space to be described later.

In addition, the upper electrode 13 further includes a ceiling electrode plate 34 formed of a conductive material contacted with an inner surface of the upper chamber 11a, an electrode plate support 35 that supports the ceiling electrode plate 34, and a buffer chamber 36 disposed below the electrode plate support 35. One end of a gas inlet pipe 38 is connected to the buffer chamber 36 and the other end thereof is connected to a processing gas supply source 39. The processing gas supply source 39 includes a control unit (not shown) for controlling the amount of supplying the processing gas. Further, a plurality of gas supply holes 40 is provided through the ceiling electrode plate 34 to allow the buffer chamber 36 to communicate with the upper chamber 11a.

Since the processing gas supplied from the processing gas supply source 39 to the buffer chamber 36 is dispersedly supplied through the gas supply holes 40 in the upper electrode 13, the upper electrode 13 serves as a shower head for the processing gas. In addition, since the upper electrode 13 is fixed onto an inner wall of the upper chamber 11a, a conductive path is formed between the upper electrode 13 and the processing vessel 11.

Two multi-pole ring magnets 41a and 41b are respectively arranged above and beneath the gate valve 19 around the upper chamber 11a of the plasma processing apparatus 10. In the multi-pole ring magnets 41a and 41b, a plurality of anisotropic segment columnar magnets (not shown) are accommodated in a casing (not shown) of a ring-shaped magnetic material and are arranged in the casing, such that a magnetic pole of one of two neighboring anisotropic segment columnar magnets is opposite to that of the other. Accordingly, magnetic force lines are created between two neighboring segment columnar magnets, and a magnetic field is generated around the processing space located between the upper electrode 13 and the lower electrode 20, so that a plasma is trapped in the processing space by the magnetic field. Further, the plasma processing apparatus 10 may be configured not to have the multi-pole ring magnets 41a and 41b.

When RIE or ashing is performed on the wafer W in the plasma processing apparatus 10, the pressure in the processing vessel 11 is adjusted to have a desired vacuum level. Then, high frequency power from the plasma generating RF power supply 28 (hereinafter, referred to as “high frequency power for generating a plasma”) and high frequency power from the ion attracting RF power supply 29 (hereinafter, referred to as “high frequency power for attracting ions”) are applied to the upper chamber 11a to generate a plasma from the processing gas.

Accordingly, ions contained in the plasma are drawn to the wafer W. To generate a plasma that has low ion energy and high electron density, the high frequency power of 40 MHz or more may be supplied from the plasma generating RF power supply 28. Further, high frequency power of 13.56 MHz or less may be supplied from the ion attracting RF power supply 29 so that ions contained in the plasma can be securely drawn toward the wafer W.

In the plasma processing apparatus 10, the high frequency power for generating a plasma has a high frequency (40 MHz or more) which tends to cause the electric field strength to be greater at a portion directly above a central portion of the wafer W in the processing space. To make the electric field strength uniformly distributed in the processing space by removing such tendency, the plasma processing apparatus 10 further includes, similarly to the conventional plasma processing apparatus, the dielectric layer 21 on the lower electrode 20. The existence of the dielectric layer 21 allows a high frequency current from the plasma-generating RF power supply 28 (hereinafter, referred to as “high frequency current for generating a plasma”) to penetrate from the central portion of the wafer W deeply to the dielectric layer 21 on the lower electrode 20 via the electrostatic chuck 22.

As a consequence, a hollow cylindrical resonance of TM mode occurs at the central portion of the lower electrode 20, so that the electric field strength can be uniformly distributed in the processing space.

When the resistance of the electrode film 37 is small, a high frequency current for generating a plasma, which propagates from the central portion of the wafer W to the electrostatic chuck 22 in a thickness direction, flows from the central portion of the electrode film 37 to the peripheral portion instead of penetrating into the dielectric layer 21, so that the high frequency current hardly reaches the dielectric layer 21. Resultantly, it is difficult to generate an electric field which originates from the high frequency current penetrating into the dielectric layer 21 and penetrates through the electrode film 37. This phenomenon will be described below.

In this embodiment, a skin depth δ of the electrode film 37 is employed as an index that indicates a degree of reduction of an electric field penetrating into the electrode film 37. The skin depth δ means a depth by which an electric field penetrating into the electrode film 37 is reduced as much as 1/e. As the skin depth δ increases, the electric field is difficult to be reduced and can easily penetrate into the electrode film 37, whereas as the skin depth δ decreases, the electric field is easily reduced and it is difficult for the electric field to penetrate into the electrode film 37. The skin depth δ can be defined by Eq. 1 as follows:

δ=(2ρᵥ/(μω))^{1/2}=(ρᵥ/(μnf))^{1/2} Eq. 1,

where μ refers to a permeability (H/m) of the electrode film 37; ω, to 2nf (n being the circular constant, and f being the frequency (Hz) of the high frequency power for generating a plasma); and ρᵥ, to a resistivity (Ω·m) of an electrode material constituting the electrode film 37. Further, an electric field E generated at the electrode film 37 can be expressed by Eq. 2 based on Maxwell's equations.

E=E₀·exp(−iωt)·exp(iz/δ)·exp(−z/δ) Eq. 2,

where, z refers to a thickness of the electrode film 37; and E₀ refers to a strength of an electric field incident onto the electrode film 37.

That is, a penetration ratio E/E₀ by which an electric field from high frequency power for generating a plasma penetrates through the electrode film 37 is proportional to “exp(−z/δ)” as represented in Eq. 3:

E/E₀∝exp(−z/δ) Eq. 3.

As the value “z/δ” is close to in Eq. 3, the penetration ratio of the electric field approaches 1.0 (100%), and as “δ” is smaller, the penetration ratio of the electric field is reduced. Here, the resistance of the electrode film 37 being small means that a resistivity ρᵥ of the electrode film 37 is small. Therefore, as the resistance of the electrode film 37 is smaller, the skin depth δ represented as “(ρᵥ/(μnf))^{1/2}” is reduced, so that it becomes difficult to generate an electric field that penetrates through the electrode film 37.

If an electric field penetrating through the electrode film 37 is less generated, a weaker hollow cylindrical resonance of TM mode occurs in the central portion of the lower electrode 20, and the electric field strength in a space directly above the central portion of the wafer W (hereinafter, referred to as “central space”) in the processing space becomes larger than the electric field strength in a space directly above the peripheral portion of the wafer W in the processing space, resulting in the increased electron density PZ at the central space. As a result, the etching rate distribution becomes non-uniform in the surface of the wafer W.

Moreover, non-uniformity in distribution of electron density of a plasma PZ in the processing space causes a DC-like current that flows from a central portion of the wafer W to a peripheral portion thereof. When the DC-like current flows through the wafer W, a gate oxide film (insulation film) 42 of the semiconductor device (hereinafter, simply referred to as “device”) placed on the wafer W may be charged up and thus can be damaged and deteriorated.

To make the etching rate uniformly distributed on the surface of the wafer W and prevent the gate oxide film 42 of the device from being deteriorated when a high frequency power for generating a plasma is supplied, it is needed to generate an electric field penetrating through the electrode film 37 by suppressing a high frequency current for generating a plasma to flow through the electrode film 37 and allowing the high frequency current to penetrate into the dielectric layer 21. For this purpose, it may be appropriate to increase δ/z in the Eq. 3. To increase δ/z, it may be appropriate to increase the skin depth δ. Since the skin depth δ is represented as “(ρᵥ/(μnf))^{1/2}” as described above, it may be appropriate to increase the resistance of the electrode film 37 by using a conductive material with high resistivity ρᵥ to increase the skin depth δ if the frequency is constant. Further, as the frequency of the high frequency power is higher, the skin depth δ is smaller (δ∝(1/ω)=(1/2nf)). Therefore, it may be appropriate to use an electrode material with a larger resistivity ρᵥ as the material constituting the electrode film 37 when the frequency of the high frequency power is adapted to be higher.

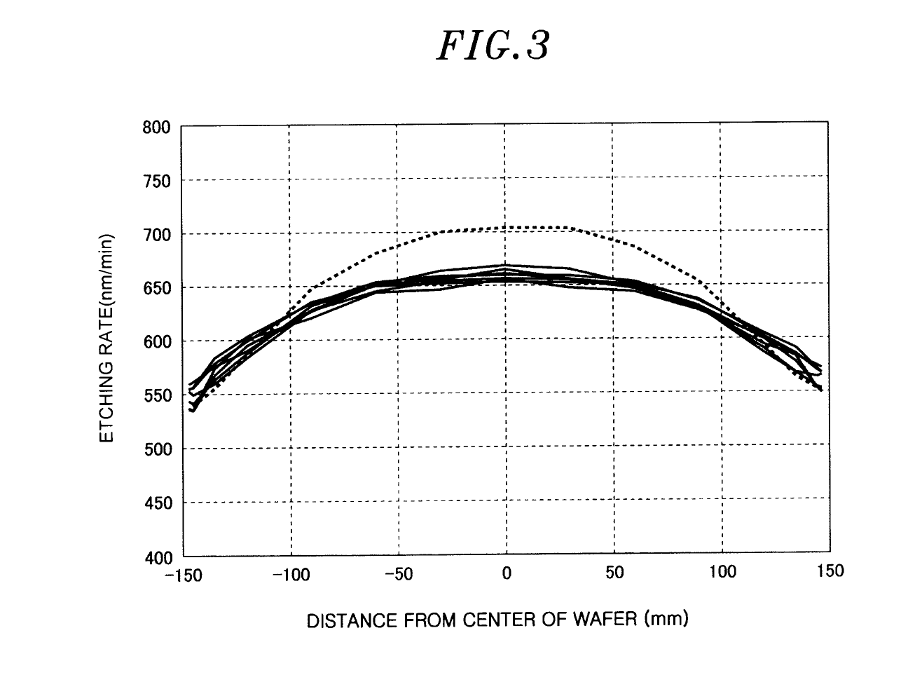

A plurality of electrode films 37, each having a different value of δ/z from that of the others, were prepared by the inventors to find δ/z that may prevent the gate oxide film 42 of the device from being deteriorated due to a charge-up damage and make the etching rate uniformly distributed on the surface of the wafer W by preventing the non-uniformity in electron density distribution of the plasma PZ in the processing space. And, ashing was performed on a photoresist of each of various wafers W in the plasma processing apparatus 10 by using the electrode film 37 thus prepared, the etching rate distribution of the photoresist on the surface of each wafer W was observed, and the results were depicted as a graph shown in FIG. 3. Hereinafter, the resistance of the electrode film 37 is represented by the surface resistivity ρₛ to remove effects by the thickness of the electrode film 37 from the resistance. The surface resistivity ρₛ refers to a resistance per unit area represented in Eq. 4, and is determined based on a property value (resistivity ρᵥ) of the electrode material constituting the electrode film 37 and the thickness of the electrode film 37:

ρₛ=ρᵥ/z(Ω/□) Eq. 4,

where δ/z (and ρₛ) of each electrode film 37 used herein was (7518, 8.9×10⁵ Ω/□), (6711, 2.67×10⁵ Ω/□), (297, 1740 Ω/□), (195, 750 Ω/□), (124, 304 Ω/□), (103, 208 Ω/□), (92, 166 Ω/□), (85, 115 Ω/□), and (47, 35 Ω/□).

In the ashing process, a single gas of O₂ was introduced as the processing gas into the upper chamber 11a by a flow rate of 100 sccm, and the high frequency power for generating a plasma and frequency thereof were set as 2000 W, and 100 MHz, no high frequency power for attracting ions was supplied.

In the graph depicted in FIG. 3, the horizontal axis refers to a distance from the center of the wafer W and the vertical axis refers to an etching rate (nm/minute). In addition, the dashed-line refer to the case where (δ/z, surface resistivity)=(47, 35 Ω/□) and solid lines refer to the cases where δ/z≧85 or surface resistivity≧115 Ω/□.

It was found in the graph depicted in FIG. 3 that the etching rate distribution can be nearly uniform on the surface of the wafer W in case that δ/z is set to be equal to or more than 85 or ρₛ is 115 Ω/□ or more. Further, it is considered that the distribution of electron density of the plasma is almost uniform in the processing space from a fact that the etching rate is nearly uniformly distributed. From this view, it was found that if δ/z is adapted to be equal to or more than 85 or ρₛ is 115 Ω/□ or more, deterioration of the gate oxide film due to a charge-up damage may be substantially prevented in the device. In this embodiment, δ/z is set to be equal to or more than 85 or ρₛ is set to be 115 Ω/□ or more based on observations of the above-described etching rate distribution.

When a high frequency power for generating a plasma and a high frequency power for attracting ions are supplied, a high frequency current for generating a plasma propagates along a surface of the outer conductive member 26 by the skin effect to reach the wafer W (depicted as a dashed line arrow in FIG. 2). On the other hand, a high frequency current from the ion attracting RF power supply 29 (hereinafter, referred to as a “high frequency current for attracting ions”) propagates along only a surface of the partition member 27 and a surface of the dielectric layer 21 (or a surface of the electrostatic chuck 22) by the skin effect since the inner conductive member 25 is partitioned by the dielectric layer 21, the electrostatic chuck 22, and the partition member 27 not to directly contact the outer conductive member 26 and the wafer W. Thus, the high frequency current for attracting ions does not flow to the wafer W directly or via the outer conductive member 26 (depicted in a solid line arrow in FIG. 2).

To evaluate effects obtainable by partitioning the inner conductive member 25 from the outer conductive member 26 by the partition member 27, the inventors prepared the lower electrode 20 where the inner conductive member 25 is partitioned from the outer conductive member 26 by the partition member 27 (hereinafter, referred to as a “mounting table in accordance with the present embodiment”) and a lower electrode which is made up of a single conductor without any partition member (hereinafter, referred to as a “conventional mounting table”), and simulated electric potential distribution in the wafer W, which appears when the lower electrode is applied with a high frequency power for generating a plasma and a high frequency power for attracting ions, as a functions of resistivity of a wafer W for each mounting table.

In the mounting table in accordance with the present embodiment, the high frequency power for attracting ions was supplied to the inner conductive member 25 and the high frequency power for generating a plasma was supplied to the outer conductive member 26.

At this time, simulation was conducted for the cases where a resistivity of the wafer W was 0.005 Ωm, 0.02 Ωm, 0.05 Ωm, 0.1 Ωm, 0.3 Ωm, and 0.5 Ωm. For each simulation, resistivity of the electrode film 37 was set 0.1 Ωm and the output of high frequency power for attracting ions was set to be 5000 W.

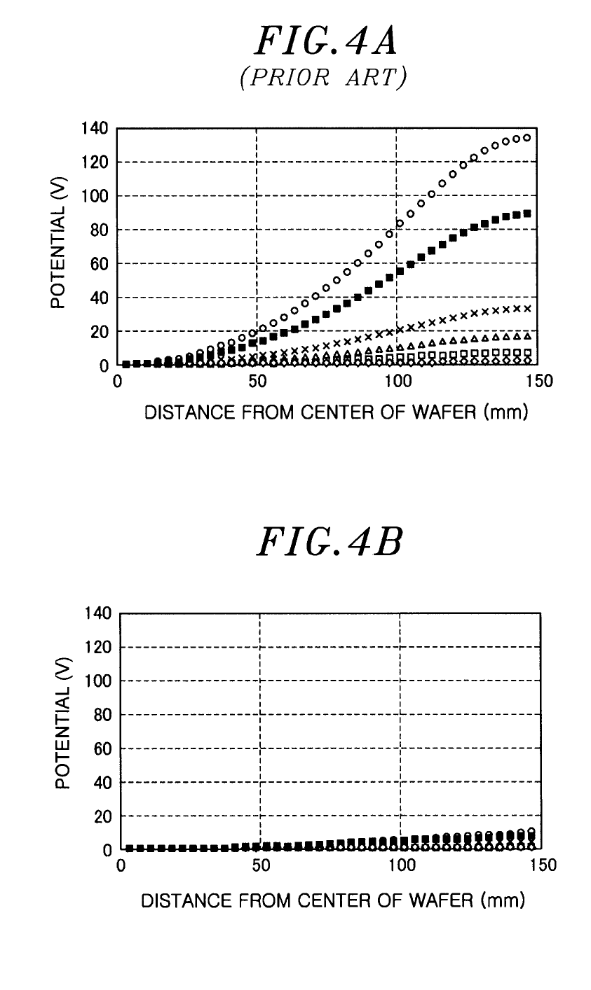

FIGS. 4A and 4B depict simulation results of a potential distribution in a wafer when the resistivity of wafer is changed while the frequency of high frequency power supplied from the ion attracting RF power supply 29 is 2 MHz, wherein FIG. 4A is a graph of illustrating simulation results for the conventional mounting table, and FIG. 4B is a graph of illustrating simulation results for the mounting table in accordance with the present embodiment.

In FIGS. 4A and 4B, when the resistivity of the wafer W was 0.005 Ωm, 0.02 Ωm, 0.05 Ωm, 0.1 Ωm, 0.3 Ωm, and 0.5 Ωm, the results are marked with “⋄”, “□”, “Δ”, “x”, “▪”, and “0”, respectively.

A comparison between graphs depicted in FIGS. 4A and 4B found that a potential difference in the mounting table in accordance with the present embodiment may be suppressed to not more than 1/10 of that in the conventional mounting table.

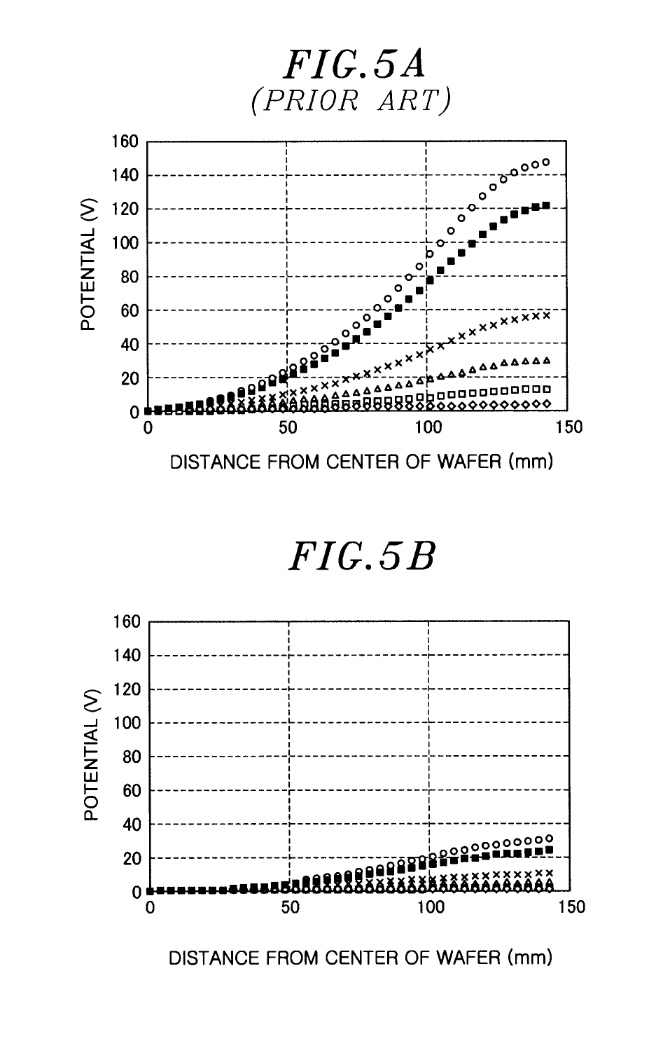

FIGS. 5A and 5B depict simulation results of a potential distribution in a wafer when the resistivity of wafer is changed while the frequency of high frequency power supplied from the ion attracting RF power supply 29 is 13 MHz, wherein FIG. 5A is a graph of illustrating simulation results for the conventional mounting table, and FIG. 5B is a graph of illustrating simulation results for the mounting table in accordance with the present embodiment.

In FIGS. 5A and 5B, when the resistance of the wafer W is 0.005 Ωm, 0.0 2Ωm, 0.05 Ωm, 0.1 Ωm, 0.3 Ωm, and 0.5 Ωm, the results are marked with “⋄”, “□”, “Δ”, “x”, “▪”, and “0”, respectively.

Comparing graphs depicted in FIGS. 5A and 5B, it is found that a potential difference in the mounting table in accordance with the present embodiment may be suppressed to not more than ⅕ of that in the conventional mounting table.

From the above, it was found that high frequency current for attracting ions is suppressed from flowing to the wafer W by applying the high frequency power for attracting ions to the inner conductive member 25 while in the lower electrode 20, the inner conductive member 25 and the outer conductive member 26 are partitioned from each other by the partition member 27 formed of a dielectric material, thus making it possible to prevent a large potential difference from occurring in the wafer W.

In addition, the inventors performed simulation on a sheath electric field strength distribution in the processing space for the mounting table of the present embodiment and the conventional mounting table to identify whether or not an electron density distribution of plasma is changed in the processing space by partitioning the inner conductive member 25 and the outer conductive member 26 from each other by the partition member 27. In this simulation for the mounting of the present embodiment also, the high frequency power for attracting ions was applied to the inner conductive member 25 and the high frequency power for generating a plasma was applied to the outer conductive member 26. And, the resistivity of the wafer W was set also 0.02 Ωm and that of the electrode film 37 was set as 0.1 Ωm.

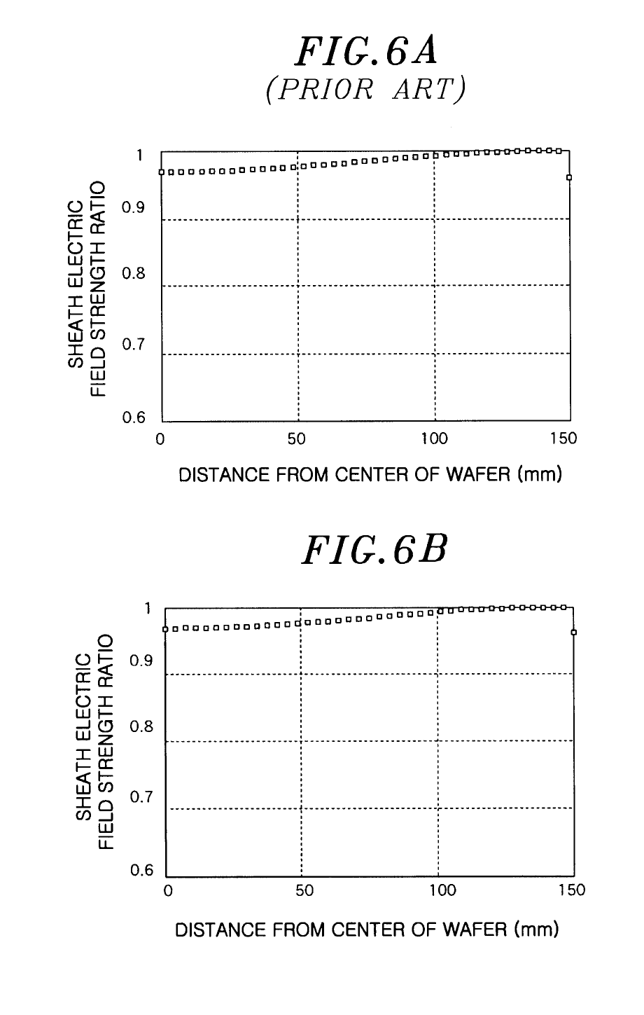

FIGS. 6A and 6B depict simulation results of a sheath electric field strength distribution in the processing space when a frequency of high frequency power supplied from the plasma generating RF power supply 28 was 100 MHz, wherein FIG. 6A is a graph illustrating simulation results from the conventional mounting table and FIG. 6B is a graph illustrating simulation results from the mounting table of the present embodiment. In FIGS. 6A and 6B, a sheath electric field strength is represented as a ratio with respect to the maximum sheath electric field strength (sheath electric field strength ratio) in the processing space.

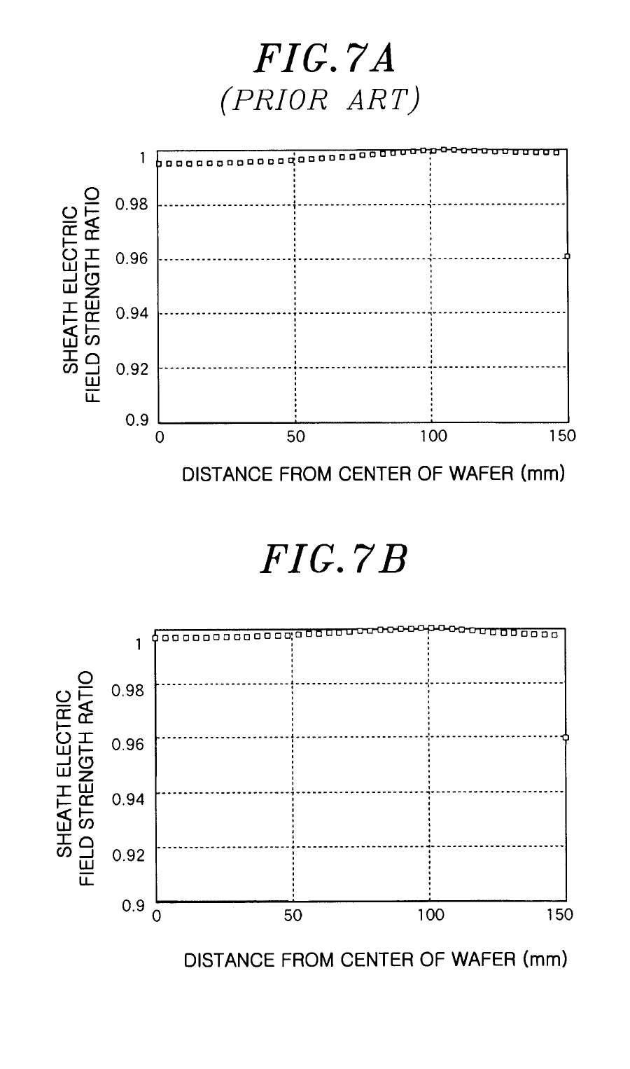

FIGS. 7A and 7B depict simulation results of a sheath electric field strength distribution in the processing space when a frequency of high frequency power supplied from the plasma generating RF power supply 28 was 40 MHz, wherein FIG. 7A is a graph illustrating simulation results from the conventional mounting table and FIG. 7B is a graph illustrating simulation results from the mounting table of the present embodiment. Also in FIGS. 7A and 7B, a sheath electric field strength is represented as a sheath electric field strength ratio.

It could be seen from the comparison between the graphs depicted in FIGS. 6A and 6B and graphs depicted in FIGS. 7A and 7B that the sheath electric field strength distribution of the mounting table of the present embodiment is similar to that of the conventional mounting table.

In view of the above, it could be also seen that an electron density distribution of plasma in the processing space is not influenced even though high frequency power to attractions is applied to the inner conductive member 25 and high frequency power for generating a plasma is simultaneously applied to the outer conductive member 26, while in the lower electrode 20, the inner conductive member 25 and the outer conductive member 26 are partitioned from each other by the partition member 27.

In the mounting table 12 in accordance with the embodiment, there is provided the electrostatic chuck 22 having the electrode film 37 that satisfies the condition “δ/z≧85”. As the skin depth δ increases, an electric field easily penetrate into the electrode film 37, so that a high frequency current is prone to penetrate deep into the electrode film 37 in a thickness direction thereof thus toward the dielectric layer 21. Accordingly, if δ/z≧85, most of the high frequency current for generating a plasma may penetrate deep into the electrode film 37 in a thickness direction thereof toward the dielectric layer 21, without flowing through the electrode film 37. As a consequence, a hollow cylindrical resonance of TM mode is generated, so that an electron density distribution of plasma in the processing space may be made uniform and a DC-like current may be prevented from being generated in the wafer W.

Further, the inner conductive member 25 is partitioned from the outer conductive member 26 by the partition member 27 formed of quartz, and portioned from the wafer W by the dielectric layer 21 or the electrostatic chuck 22 formed of a dielectric material. Thus, a high frequency current for attracting ions flowing through the inner conductive member does not flow to the wafer directly or via the outer conductive member 26. This can prevent the high frequency current for attracting ions from causing a large potential difference in the wafer W. Consequently, it is possible to prevent deterioration of the gate oxide film 42 due to a charge-up damage to the device.

Further, in the mounting table 12 in accordance with the embodiment, the electrode film 37 satisfies a condition “115 Ω/□≦ρs”. As the surface resistivity of the electrode film 37 increases, it is difficult for a high frequency current to flow through the electrode film 37, so that it is easy for the high frequency current to penetrate into the electrode film 37 in a thickness direction thus to penetrate. Accordingly, if 115 Ω/□≦ρs, a high frequency current for generating a plasma, which propagates from the wafer W mostly may pass through the electrode film 37 in a thickness direction to penetrate into the dielectric layer 21 without flowing through the electrode film 37. As a consequence, a hollow cylindrical resonance of TM mode may be generated so that an electron density of a plasma may be nearly uniformly distributed in the processing space.

Next, a mounting table in accordance with a second embodiment of the present invention will be described.

The configuration and operation of the second embodiment are basically identical to those of the first embodiment and therefore repetitive descriptions on the configuration and operation will be omitted. Hereinafter, the configuration and operation different from those of the first embodiment will be only described

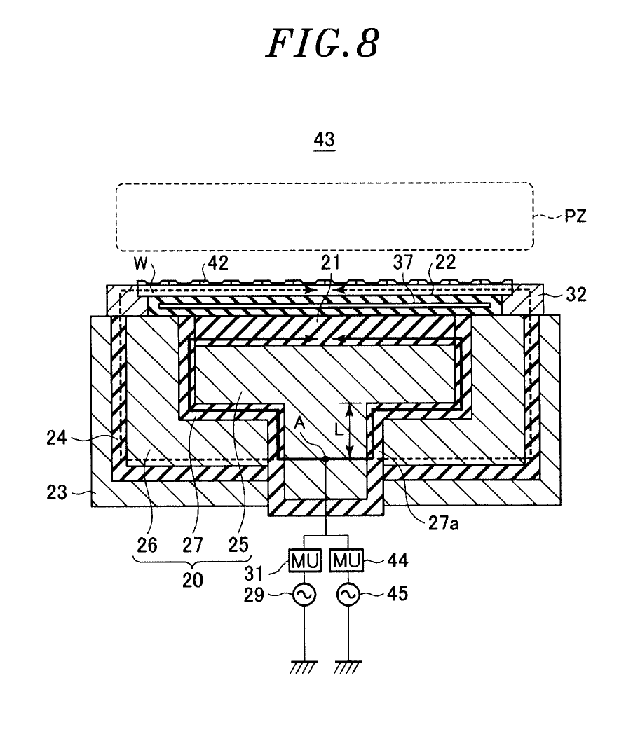

FIG. 8 is an expanded cross sectional view schematically illustrating a configuration around a mounting table in accordance with an embodiment of the present invention.

Referring to FIG. 8, a mounting table 43 includes a plasma generating RF power supply 45 for generating a plasma, which is connected to the inner conductive member 25 via a matching unit (MU) 44 instead of the plasma generating RF power supply 28 connected to the outer conductive member 26 via the matching unit 30. A feed line from the ion attracting RF power supply 29 and a feed line from the plasma generating RF power supply 45 are merged as a single feed line, which is in turn connected to the inner conductive member 25.

Further, the partition member 27 includes an extension 27a extended toward the wafer W electrostatically adsorbed onto the electrostatic chuck 22 from a location where the line from the plasma generating RF power supply 45 for generating a plasma is connected to the inner conductive member 25 (indicated with ‘A’ in FIG. 8) to have a length L of 10 mm or more.

In the mounting table 43, a high frequency current for attracting ions propagates only along a surface of the partition member 27 and a surface of the dielectric layer 21 (or a surface of the electrostatic chuck 22) by the skin effect as in the mounting table 12 and does not flow to the wafer W directly or via the outer conductive member 26 (this is indicated by a solid line arrow in FIG. 8). On the other hand, a high frequency current for generating a plasma is also directed to a surface of the partition member 27. However, since the partition member 27 includes the extension 27a whose dielectric constant causes an effect of shortening the wavelength, an inductive resonance is generated within the partition member 27 (including the extension 27a).

As a result, the high frequency current for generating a plasma propagates the partition member 27 and flows to the outer conductive member 26. Further, the high frequency current for generating a plasma propagates along a surface of the outer conductive member 26 by the skin effect to reach the wafer W (this is indicated by a dashed line arrow in FIG. 8).

At this time, a degree by which the high frequency current for generating a plasma propagates the partition member 27 depends on a dielectric constant of the dielectric material that makes up the partition member 27.

The inventors simulated a sheath electric field strength distribution in the processing space with respect to a plurality of dielectric constants (1, 5, 10, 50, 100, 130, and 150) to find out a dielectric constant by which a high frequency current for generating a plasma may effectively propagate the partition member 27. At this time, a resistivity of the wafer W was set 0.1 Ωm, a resistivity of the electrode film 37 was set 0.01 Ωm, and an output of the high frequency power for generating a plasma was set to be 5000 W.

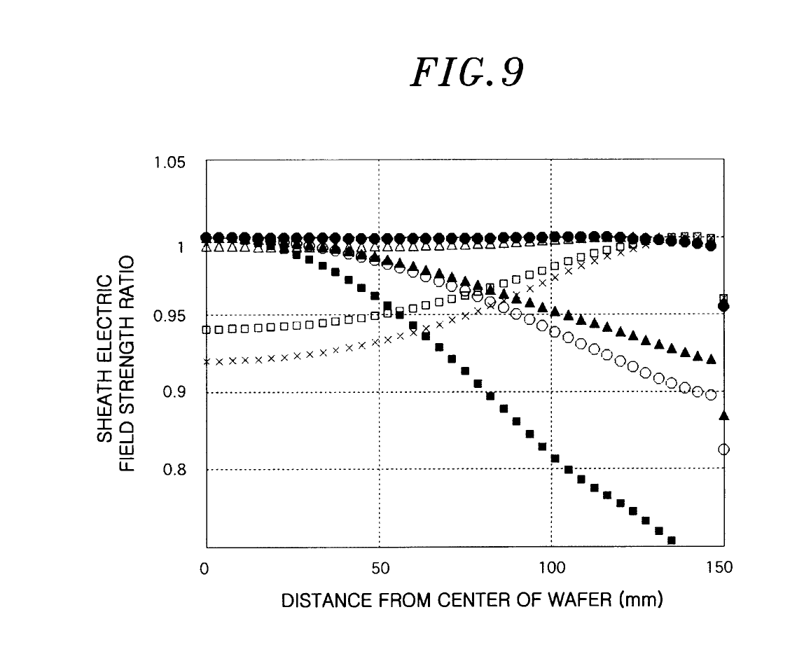

FIG. 9 is a graph illustrating simulation results of a sheath electric field strength distribution in the processing space in case that a resistivity of the partition member is changed.

Also in FIG. 9, a sheath electric field strength is represented as a sheath electric field strength ratio. When the resistivity of the partition member 27 is 1, 5, 10, 50, 100, 130, and 150, the results are marked with “▪”, “▴”, “”, “x”, “□”, “Δ”, and “∘”, respectively.

It can be seen from the graph depicted in FIG. 9 that when the dielectric constant is 10 or 130, a sheath electric field strength distribution becomes nearly uniform, and when the dielectric constant is 50 or 100, the sheath electric field strength becomes weak around a central portion of the wafer W, while the dielectric constant is 1, 5, or 150, a sheath electric field strength becomes strong at the central portion of the wafer W.

That is, it was found that if the dielectric constant ranges from 10 to 130, a hollow cylindrical resonance of TM mode occurs at the central portion of the lower electrode 20. Therefore, an electric field strength distribution becomes uniform in the processing space, or an electric field strength becomes weak at a processing space directly above a central portion of the wafer W. On the contrary, if the dielectric constant is 1, 5, or 150, a hollow cylindrical resonance of TM mode does not occur at the central portion of the lower electrode 20 and thus an electric field strength becomes strong at a processing space directly above a central portion of the wafer W.

From the above, it can be contemplated that if the dielectric constant ranges from 10 to 130, a high frequency current for generating a plasma mostly is passed through the partition member 27 to reach the wafer W and flows along the wafer W, while if the dielectric constant is 1, 5, or 150, the high frequency current for generating a plasma hardly passes through the partition member 27 and does not flow along the wafer W. In this embodiment, the dielectric constant of the dielectric material constituting the partition member 27 is set to range from 10 to 130 based on the simulation results of the sheath electric field strength distribution in the processing space when the dielectric constant of the dielectric constant of the partition member 27 is changed.

In the mounting table 43 in accordance with this embodiment, since the dielectric constant of the dielectric material forming the partition member 27 is 10 to 130, a high frequency current for generating a plasma can readily pass through the partition member 27 to thereby flow from the inner conductive member 25 to the outer conductive member 26 to reach the wafer W. Thereafter, the high frequency current for generating a plasma flows along the wafer W, and thus generate the hollow cylindrical resonance of TM mode. Thus, an electron density distribution of plasma PZ in the processing space can be nearly uniform in the processing space, and a DC-like current can be prevented from being generated in the wafer W. As a consequence, it can be possible to prevent deterioration of the gate oxide film 42 due to a charge-up damage to the device.

In the above-described mounting table 43, further, the ion attracting RF power supply 29 and the high frequency power supply 45 for generating a plasma are connected to the inner conductive member 25 through a single line, so that the configuration of the mounting table 43 may be simplified.

Although the semiconductor wafer W is exemplified as a substrate which is subjected to RIE or ashing in the above embodiments, the substrate is not limited thereto. For example, the substrate may be a glass substrate such as LCDs (Liquid Crystal Displays) or FPDs (Flat Panel Displays).

In accordance with a mounting table for use in a plasma processing apparatus described above, it may be possible to generate a plasma that has low ion energy and high electron density.

Further, it may be possible to certainly attract ions from a plasma into a substrate mounted on the mounting table. While the invention has been shown and described with respect to the embodiment, it will be understood by those skilled in the art that various changes and modifications may be made without departing from the scope of the invention as defined in the following claims.

What is claimed is:

1. A mounting table for use in a plasma processing apparatus, on which a substrate is mounted, comprising:
an inner conductive member connected to an ion attracting RF power supply;
an outer conductive member connected to a plasma generating RF power supply, the outer conductive member surrounding the inner conductive member;
a partition member formed of a dielectric material, the partition member partitioning between the inner conductive member and the outer conductive member;
an electrostatic chuck formed of a dielectric material and arranged between the substrate and the inner conductive member, and between the substrate and the outer conductive member; and
a dielectric layer arranged between the electrostatic chuck and the inner conductive member to conceal the inner conductive member from the electrostatic chuck,
wherein the electrostatic chuck includes an electrode film that is connected to a high voltage DC power supply and satisfies the following condition:
δ/z≧85,
where δ=(ρᵥ/(μnf))_{1/2}, and z refers to a thickness of the electrode film; δ, to a skin depth of the electrode film relative to high frequency power supplied from the high frequency power supply for generating a plasma; f, to a frequency of high frequency power supplied from the high frequency power supply for generating a plasma; n, to a circular constant; μ, to a magnetic permeability of the electrode film; and ρᵥ, to a resistivity of the electrode film.

2. The mounting table of claim 1, wherein the plasma generating RF power supply supplies high frequency power having a frequency of 40 MHz or more.

3. The mounting table of claim 1, wherein the ion attracting RF power supply supplies high frequency power having a frequency of 13.56 MHz or less.

4. A mounting table for use in a plasma processing apparatus, on which a substrate is mounted, comprising:
an inner conductive member connected to an ion attracting RF power supply;
an outer conductive member connected to a plasma generating RF power supply, the outer conductive member surrounding the inner conductive member;
a partition member formed of a dielectric material, the partition member partitioning between the inner conductive member and the outer conductive member from each other;
an electrostatic chuck formed of a dielectric material and arranged between the substrate and the inner conductive member, and between the substrate and the outer conductive member; and
a dielectric layer arranged between the electrostatic chuck and the inner conductive member to conceal the inner conductive member from the electrostatic chuck,
wherein the electrostatic chuck includes an electrode film that is connected to a high voltage DC power supply and satisfies the following condition:
115 Ω/□≦ρₛ and,
where ρₛ refers to a surface resistivity of the electrode film.

5. The mounting table of claim 4, wherein the plasma generating RF power supply supplies high frequency power having a frequency of 40 MHz or more.

6. The mounting table of claim 4, wherein the ion attracting RF power supply supplies high frequency power having a frequency of 13.56 MHz or less.

7. A mounting table for use in a plasma processing apparatus, on which a substrate is mounted, comprising:
an inner conductive member connected to an ion attracting RF power supply and a plasma generating RF power supply;
an outer conductive member surrounding the inner conductive member;
a partition member formed of a dielectric material, the partition member partitioning between the inner conductive member and the outer conductive member;
an electrostatic chuck formed of a dielectric material and arranged between the substrate and the inner conductive member, and between the substrate and the outer conductive member; and
a dielectric layer arranged between the electrostatic chuck and the inner conductive member to conceal the inner conductive member from the electrostatic chuck, wherein the electrostatic chuck includes an electrode film that is connected to a high voltage DC power supply,
wherein a dielectric constant of the partition member ranges from 10 to 130, and wherein the electrode film satisfies the following condition:
δ/z≧85,
where δ=(ρᵥ/(μnf))^{1/2}, and z refers to a thickness of the electrode film; δ, to a skin depth of the electrode film relative to high frequency power supplied from the plasma generating RF power supply; f, to a frequency of high frequency power supplied from the plasma generating RF power supply; n, to the circular constant; μ, to a magnetic permeability of the electrode film; and ρᵥ, to a resistivity of the electrode film.

8. The mounting table of claim 7, wherein the partition member has an extension that has a length of at least 10 mm or more and extends toward the mounted substrate.

9. The mounting table of claim 7, wherein the plasma generating RF power supply supplies high frequency power having a frequency of 40 MHz or more.

10. The mounting table of claim 7, wherein the ion attracting RF power supply supplies high frequency power having a frequency of 13.56 MHz or less.

11. A mounting table for use in a plasma processing apparatus, on which a substrate is mounted, comprising:
an inner conductive member connected to an ion attracting RF power supply and a plasma generating RF power supply;
an outer conductive member surrounding the inner conductive member;
a partition member formed of a dielectric material, the partition member partitioning between the inner conductive member and the outer conductive member;
an electrostatic chuck formed of a dielectric material and arranged between the substrate and the inner conductive member, and between the substrate and the outer conductive member; and
a dielectric layer arranged between the electrostatic chuck and the inner conductive member to conceal the inner conductive member from the electrostatic chuck, wherein the electrostatic chuck includes an electrode film that is connected to a high voltage DC power supply,
wherein a dielectric constant of the partition member ranges from 10 to 130, and wherein the electrode film satisfies the following condition:
115 Ω/□≧ρₛ,
where ρₛ refers to a surface resistivity of the electrode film.

12. The mounting table of claim 11, wherein the partition member has an extension that has a length of at least 10 mm or more and extends toward the mounted substrate.

13. The mounting table of claim 11, wherein the plasma generating RF power supply supplies high frequency power having a frequency of 40 MHz or more.

14. The mounting table of claim 11, wherein the ion attracting RF power supply supplies high frequency power having a frequency of 13.56 MHz or less.
